(19) United States
(12) Patent Application Publication
(10) Pub. No.: US 2009/0085596 A1
(43) Pub. Date: Apr. 2, 2009

(54) SYSTEM AND METHOD FOR TESTING SEMICONDUCTOR DEVICES

(75) Inventors: Wolfgang Ruf, Friedberg (DE); Michael Schittenhelm, Poing (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/863,900

(22) Filed: Sep. 28, 2007

(51) Int. Cl. G01R 31/02

(52) U.S. Cl. 324/761

(57) ABSTRACT

A system for testing semiconductor devices is disclosed. In one embodiment, the test system being configured to be electrically connected via parallel wiring paths to a plurality of contact pins of a number of devices under test. The test system having at least one signal distribution matrix arranged in the wiring path to provide signals for testing and/or power supply to the devices.

### BACKGROUND

The present invention relates to a system and a method for testing for testing functionality of integrated circuits, semiconductor devices, dies or chips. In one embodiment, the present invention relates to a system and a method for testing the core, interfaces and/or the clock frequency or speed of integrated circuits, semiconductor devices, dies or chips, logic or memory semiconductor components, e.g., dynamic random access memories (DRAMs).

In semiconductor manufacturing, a plurality of integrated circuits or devices are formed on a semiconductor substrate or wafer, and after completing the fabrication processes, the devices formed on the wafer may be cut from the wafer into dies and packaged into separate chips, which are then tested individually to ensure that each chip performs according to the required specifications. For connecting the test system with the devices to be tested, conventional test systems usually include a so called probe card providing the interface between the test system and the semiconductor devices under test.

There exist different test systems for testing different functionalities of semiconductor devices. For cost-reduced testing of DRAMs a cost-optimized test strategy provides separate test processes for testing the core of the DRAM, i.e. the “core test” and for testing the interface or interfaces of the DRAM, i.e. the so called “interface test”.

The core test may be performed at low frequency (up to 200 MHz). This also facilitates the design of the test modes and does not cause high accuracy requirements to the test system, so that older test systems can be used further on. The core test examines the functionality of every single memory cell of the DRAM which results in long test times. To keep the test costs within reasonable limits it is known to perform the core test in a high-parallel manner, wherein the driver pins of the test system can be connected with up to four devices under test (DUT) and only four input/output (IO) pins are required per device under test. However, the core test in a high-parallel manner leads to a restriction not all input/output (IO) pin of the devices under test (DUT) can be connected.

During the interface test, the interface of the DRAM may be tested in a customized mode. To this end, all pins of the semiconductor device or DRAM have to or should be connected with the test system to check the fulfilling of the timing requirements of the individual pins and the functionality of the entire device. In one embodiment, the data paths which are not accessible with the test mode at the application clock frequency (e.g., devices according to the standard double data rate 2 (DDR2) are using a clock frequency of 400 MHz or 533 MHz) have to or should be tested.

To extend the test capacity of the test system, only test systems are used which are also suited for an interface test, due to their technical further development with respect to test frequency rate and timing accuracy. However, such interface test systems are more expensive than core test systems and the full testing of all functionalities requires different test systems.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIGS. 1A and 1B schematically illustrate known systems for testing semiconductor.

FIG. 2 schematically illustrates a system for testing semiconductor devices according one embodiment.

### DETAILED DESCRIPTION

In the following Detailed Description, reference is made to the accompanying drawings, which form a part hereof, and in which is illustrated by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One or more embodiments re-unite separate test processes or test insertions, i.e. the core test and the interface test, but to maintain the high parallelism of the core test and is able to perform an interface test with all the pins of the DUTs.

Furthermore, the present embodiments aim to shift or transfer as many test contents as possible or all test contents from expensive interface test systems to cost-efficient core test systems while maintaining the very high parallelism. The number of test contents which can be shifted or transferred from expensive interface test systems to cost-efficient core test systems depends on the timing accuracy requirement of the device or product to be tested.

In conventional test systems, up to four devices under test must share the same input/output channels or input/output contact pins (IO pins) of the test system. Thus, the parallelism is four times as high as originally provided, but all the data pins (DQ pins) of every device under test must be connected with the test system and have to be configured to be evaluated separately so as to check, for instance, contact, leakage for every pin, to examine the data path and the interface functionality, and to possibly test interface timing parameters.

A system and method for testing semiconductor devices, dies or chips is provided with integrated testing of core and speed of the semiconductor devices, e.g., DRAMs. In a core test, only a part of the input/output pins of the devices under test need to be connected with the test channels of the test system. Therefore, several devices under test can be core tested in parallel.

DRAMs may have a different number of data pins and input/output pins (I/O pins), e.g., DRAMs with four data pins (organisation x4), eight data pins (organisation x8), and sixteen data pins (organisation x16). If, for instance, the test system includes eight test channels or input/output channels and the devices under test have eight input/output pins, e.g., DRAMs with organisation x8 (8 I/O pins), the test system may perform a core test on two DRAMs with organisation x8 in parallel by contacting only four input/output pins of each device under test.

To achieve the full test coverage of the interface test, all input/output pins of the device under test should be connected. Therefore, a sufficient number input/output pins of the test system has to be connected with all input/output pins of the device under, respectively. If, for instance, the test system includes eight test channels and the devices under test have eight input/output pins, e.g., DRAMs with organisation x8 (8 I/O pins), the test system may perform an interface test on only one DRAM with organisation x8 at a time contacting all eight input/output of the device during the test.

According to one embodiment, a test system with, for instance, eight test channels can perform an interface test in a subsequent manner four times for DRAMs with organisation x16 (16 I/O pins), twice for DRAMs with organisation x8 (8 I/O pins), and once for DRAMs with organisation x4 (4 I/O pins), depending on the organization or wiring of the semiconductor device using the less expensive low speed testers (core tester). Thus, a number of devices can be interface tested in a subsequent manner in one so called “touch down” of the test system, whereas the configuration of the distribution matrix provides the necessary contact between the test channels and the input/output pins of the devices under test. This might result in a test time prolongation. However, the system and method according to the present invention may save a complete test insertion using the expensive high speed testers.

According to one or more embodiments, a frequency doubling system (FDS) may be coupled with the relay matrix. The frequency doubling system (FDS) may be implemented in a so called applied semiconductor integrated circuit (ASIC). The ASIC is controlled by the test system and controls the devices under test. Thus, the AISIC may provide a doubling of the test frequency and may provide enhancement of signal integrity.

In one embodiment, the distribution matrix is configured to connect or to disconnect a number of wiring paths to the contact pins of the devices. The distribution matrix is configured to be configured in different configurations so that one or more tester channel of a test system may be connected with different contact pins of one or more devices under test. Thereby, the distribution matrix may be configured to distribute signals for testing and/or power supply to a first group of wiring paths or to a second group of wiring paths connected to contact pins of the devices.

In one embodiment, the first group of wiring paths may be different from the second group of wiring paths. In another embodiment, the second group of wiring paths may partly or completely include the first group of wiring paths.

Furthermore, the distribution matrix may be configured to distribute signals for testing and/or power supply to all contact pins of a device under test or to a part of the contact pins of the device.

In one embodiment, the distribution matrix includes at least one relay matrix with a plurality of relays or switches arranged in the wiring paths connected to the contact pins of the devices. The distribution matrix may include at least one relay matrix with a plurality of relays or switches arranged in the wiring paths connected to the contact pins of the devices.

In addition, the distribution matrix may include a number of matrix sections with a plurality of relays or switches arranged in the wiring paths connected to the contact pins of the devices. The distribution matrix may be part of the test system or a part of an interface between a test system for testing semiconductor devices and the semiconductor devices to be tested. The distribution matrix may be part of a so called probe card or socket board.

In one embodiment, the at least one relay or switch is arranged in each wiring path connected to the contact pins of the devices. The relays or switches may be configured to connect or to disconnect a wiring path connected to a contact pin of the devices. Furthermore, the relays or switches may be configured to distribute signals for testing and/or power supply provided by the test system to a first wiring path or to a second wiring path connected to contact pins of the devices.

In one embodiment, the distribution matrix may provide a branching in the wiring paths to connect the test system to a first group of wiring paths or to a second group of wiring paths connected to contact pins of the devices. The branching may be configured to connect a number of tester channels of the test system to a first group of wiring paths or to a second group of wiring paths connected to contact pins of the devices. Furthermore, at least one branching may be installed in a wiring path providing a bifurcation of the tester channel.

The switching ability of the distribution matrix or the relay matrix according to the present invention offers the choice of connecting only a part of data pins or connecting all data pins of the devices under test. Thereby, core testing systems can be enabled or can be used to perform both core testing and interface testing on semiconductor devices. This is due to the circumstance that for core testing only a part of data pins of the devices under test have to be connected to the test system, whereas for interface testing, connection of all data pins of the devices to the test system is necessary. Thus, the present invention saves a complete test insertion using the expensive high speed testers for interface testing.

The arrangement of the signal distribution matrix in the wiring path provides the desired distribution of signals from a tester channel to the input/output pins of the devices under test. For instance, the signal of a tester channel can be forwarded by the distribution matrix to certain contact pins of devices under test. In one embodiment, the signal of the tester channels of the test system can be forwarded by the distribution matrix to a certain number or all contact pins of the devices under test.

For distributing test signals or power supply provided by the test system to the input/output pins of the devices under test, the distribution matrix may include a branching which distributes the signal of the tester channels to a plurality of contact pins of devices under test. In one embodiment, the distribution matrix may include bifurcations which distribute the signal of a tester channels to a number of contact pins of devices under test. Further, the distribution matrix may connect two or more tester channels with one contact pin of a device under test. Thus, a simple frequency doubling may be provided.

To achieve the full test coverage for the interface test, the test pattern will, however, be performed four times with x16, twice with x8, and once with x4, depending on the organization. This might result in a test time prolongation, however, a cost saving effect can be achieved by using cost-efficient core test systems instead of expensive interface test systems while maintaining high parallelism. According to one embodiment, the test progress may be controlled by separate chip select pins, comparable to the test of stacked DRAMs.

According to another embodiment, a number of calibration files which is a set of propagation delays, e.g., two calibration files (calfiles x8) or four calibration files (calfiles x16) is used for optimized timing measurements in the individual configurations caused by the branching of the distribution matrix, if marginalities of the devices under test (DUTs) so require. The calibration files may be implemented in the test system and provide a desired delay of the test signals. Thus, the desired timing of the test signals generated by the test system and transferred to the devices under test can be achieved.

According to another embodiment, an interface or probe card is provided for connecting a test system for testing semiconductor devices with the semiconductor devices to be tested including:

at least one tester channel;

a plurality of parallel wiring paths, each wiring path configured to have a first end coupled to the tester channel and a second end configured to be coupled to an input of separate devices under test; and

a distribution matrix arranged in the wiring path to provide signals for testing and/or power supply to the devices. The distribution matrix may be configured to connect the tester channel with a first group of wiring paths or with a second group of wiring paths connected to inputs of the devices.

The present embodiments provide for shifting as many test contents as many as possible or of even all test contents (depending on the timing accuracy requirement of the device or product to be tested) from expensive interface test systems to cost-efficient core test systems while maintaining high parallelism.

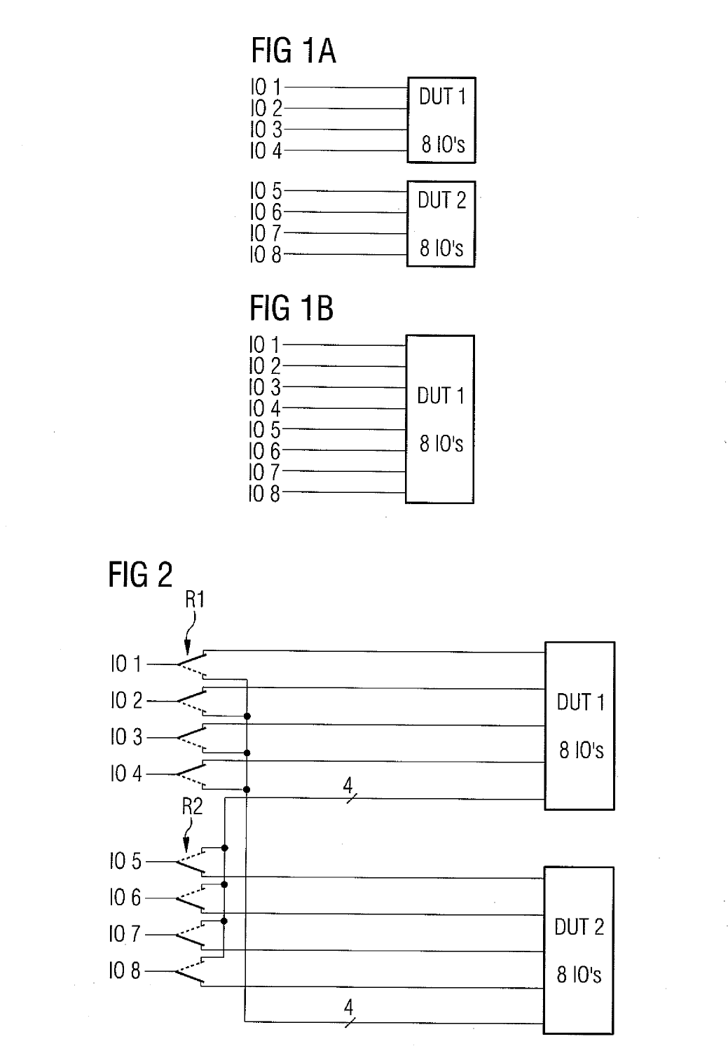

The attached Figures refer to a test system with eight test channels or input/output pins (IO1-IO8) and to devices under test with eight input/output pins (DQ0-DQ7), respectively. FIGS. 1A and 1B illustrate a schematic illustration of a conventional test system using the above mentioned advanced compression test mode in a core test and in an interface test. FIG. 1A illustrates a test configuration for a core test of a first and second device under test DUT1 and DUT2 with eight DQ data pins or input/output pins (IO's), respectively; and FIG. 1B illustrates a test configuration for a interface test of a semiconductor device under test DUT1 including eight DQ data pins or input/output pins (IO's).

Referring to FIG. 1A, there are four input/output channels 101, 102, 103 and 104 of a test system or tester (not illustrated) electrically contacting four of the eight input/output pins of a first device under test DUT1. Furthermore, there are another four input/output channels 105, 106, 107 and 108 of the test system or tester electrically contacting four input/output pins of a second semiconductor device under test DUT2 with eight input/output pins.

The core test examines the functionality of every single memory cell of the DRAM which causes long test times and high test costs. For reducing the test times, the core test is usually performed in a high-parallel manner, wherein the driver channels of the test system can be connected with up to four devices under test (DUT) and only four input/output (IO) pins of the test system are required per device under test. Thus, in the core test situation illustrated in FIG. 1A, the test system with eight test channels or input/output pins (IO's) can perform a core test for two devices under test with eight input/output pins (organisation x8) in parallel.

FIG. 1B schematically illustrates a test system for testing the interface functionality of a semiconductor device. This interface test system provides eight input/output channels IO1, IO2, . . . , IO8 of a tester (not illustrated). The interface test of a DRAM may be tested in a customized mode. To this end, each of the eight input/output channels IO1, IO2, . . . , IO8 of the test system need to be in electrical contact with one pin of a device under test DUT1 with eight input/output pins to check the fulfilling of the timing requirements of the individual pins and the functionality of the entire device. The interface test had to be performed by cost-intensive interface test systems so far.

FIG. 2 schematically illustrates a system for testing semiconductor devices according one embodiment. In this embodiment, the test system or tester (not illustrated) provides eight test channels or input/output channels IO1-IO8. The input/output channels IO1-IO8 of the test system are in electrical contact with input/output pins of a first device under test DUT1 and a second device under test DUT1, wherein each device under test DUT1 and DUT2 include eight input/output pins. The test signals may include data, control signals and/or address signals.

The input/output channels IO1-IO8 of the test system are contacted with the input/output pins of the devices under test DUT1 and DUT2 via a distribution matrix. The distribution matrix may be configured in different configurations so that one or more tester channel of a test system may be connected with different contact pins of one or more devices under test. Thereby, the distribution matrix may distribute signals for testing and/or power supply to a first group of wiring paths or to a second group of wiring paths connected to contact pins of the devices in dependence on the configuration of the distribution matrix.

In the embodiment illustrated in FIG. 2 the distribution matrix is implemented as a relay matrix or a so called socket board with two relay sections R1 and R2. The upper input/output channels IO1-IO4 of the test system are contacted with the input/output pins of the devices under test DUT1 and DUT2 via a first relay matrix section R1, and the lower input/output channels IO5-IO8 of the test system are contacted with the input/output pins of the devices under test DUT1 and DUT2 via a second relay matrix section R2.

The relay matrix sections R1 and R2 include a number of separate relays or switches for each input/output channel IO1-IO8 of the tester. The relays or switches may be set or configures in two different positions, thereby contacting the input/output channels IO1-IO8 of the test system with different input/output pins of the devices under test DUT1 and DUT2, respectively.

In a first configuration of the distribution matrix, the relay matrix sections R1 and R2 are in a first position as indicated by continuous lines in FIG. 2, wherein the upper four input/output channels IO1-IO4 contact four input/output pins (DQ0-DQ3) of the first device under test DUT1; and the lower four input/output channels IO5-IO8 of the test system contact four input/output pins (DQ0-DQ3) of the second device under test DUT2.

In a second configuration of the distribution matrix, the relay matrix sections R1 and R2 are in a second position as indicated by dotted lines in FIG. 2, wherein the upper four input/output channels IO1-IO4 of the test system contact four input/output pins (DQ4-DQ7) of the second device under test DUT2; and the lower four input/output channels IO5-IO8 contact four input/output pins (DQ4-DQ7) of the first device under test DUT1.

For a core test of the first and second devices under test DUT1 and DUT2, the relay matrix sections R1 and R2 for all input/output channels IO1-IO8 of the test system may be in the first relay position as indicated by continuous lines. Due to this configuration of the distribution matrix, the upper four input/output channels IO1-IO4 of the test system are contacting four input/output pins (DQ0-DQ3) of the first device under test DUT1, and the lower four input/output channels IO5-IO8 of the test system are contacting four input/output pins (DQ0-DQ3) of the second device under test DUT2.

In one embodiment, for a core test of the first and second devices under test DUT1 and DUT2, the relay matrix sections R1 and R2 for all input/output channels IO1-IO8 of the test system may be in the second relay position as indicated by dotted lines. In this configuration of the distribution matrix, the upper four input/output channels IO1-IO4 of the test system are contacting four input/output pins (DQ4-DQ7) of the second device under test DUT2, and the lower four input/output channels IO5-IO8 of the test system are contacting four input/output pins (DQ4-DQ7) of the first device under test DUT1.

When both relay matrix sections R1 and R2 are in the first relay position as indicated by continuous lines or both relay matrices R1 and R2 are in the second relay position as indicated by dotted lines, each device under test DUT1 and DUT2 is contacted by four test channels (IO1-IO8 or IO5-IO8), respectively, so that a core test can be preformed on both devices under test DUT1 and DUT2 at the same time.

For performance of an interface test on the first device under test DUT1, the first relay matrix section R1 with the upper input/output channels IO1-IO4 of the test system may be in the first relay position as indicated by continuous lines, and the second relay matrix section R2 with the lower input/output channels IO5-IO8 of the test system may be in the second relay position as indicated by dotted lines. In this configuration of the distribution matrix, the upper four input/output channels IO1-IO4 of the test system are contacting four input/output pins (DQ0-DQ3) of the first device under test DUT1, and the lower four input/output channels IO5-IO8 of the test system are contacting four input/output pins (DQ4-DQ7) of the first device under test DUT1, too. Thus, all (eight) input/output pins of the first device under test DUT1 are contacted and an interface test can be performed.

To conduct an interface test on the second device under test DUT2, the first relay matrix section R1 with the upper input/output channels IO1-IO4 of the test system may be in the second relay position as indicated by dotted lines, and the second relay matrix section R2 with the lower input/output channels IO5-IO8 of the test system may be in the first relay position as indicated by continuous lines. In this configuration of the distribution matrix, the upper four input/output channels IO1-IO4 of the test system are contacting four input/output pins (DQ4-DQ7) of the second device under test DUT2, and the lower four input/output channels IO5-IO8 of the test system are contacting four input/output pins (DQ0-DQ3) of the second device under test DUT2, too. Thus, all (eight) input/output pins of the second device under test DUT2 are contacted and an interface test can be performed.

According to one or more embodiments, the relay matrix or socket board R1 and R2 between the devices under test DUT1 and DUT2 and the input/output channels (IO) of the tester may be adjusted in a manner so that:

Four devices under test (DUT) can respectively be connected with their equivalent data pins (DQs), e.g., DQ0-DQ7, with tester IOs, e.g., 4 DUTs*4 pins are connected to 16 tester input/output channels (IO), so as to perform the core test by using test modes.

Only one device under test, with a DUT organization x16, is connected with all DUT contact pins with 16 input/output channels of the test system so as to perform the interface test.

Two devices under test (DUT), with a DUT organization x8, are respectively connected with all DUT IOs with 16 tester IOs so as to perform the interface test.

According to one embodiment, for a core test of a first and second device under test DUT1 and DUT2, e.g., with a wiring for organization x8, the relay sections R1, R2 of the distribution matrix can be configured as indicated in the following table:

| Tester IO pin | DUT pin relay pos. 1 | DUT pin relay pos. 2 |
|---|---|---|
| IO1 | DUT1 DQ0 | DUT2 DQ4 |
| IO2 | DUT1 DQ1 | DUT2 DQ5 |
| IO3 | DUT1 DQ2 | DUT2 DQ6 |
| IO4 | DUT1 DQ3 | DUT2 DQ7 |
| IO5 | DUT2 DQ0 | DUT1 DQ4 |
| IO6 | DUT2 DQ1 | DUT1 DQ5 |
| IO7 | DUT2 DQ2 | DUT1 DQ6 |
| IO8 | DUT2 DQ3 | DUT1 DQ7 |

The first column of the table indicates the number of input/output channels of the test system; the second column of the table indicates which data pin (DQ0-DQ7) of the devices under test DUT1 or DUT2 is connected to the respective input/output channel IO1-IO8 of the test system, when the relay matrix sections R1 and R2 are in the first position. The third column of the table indicates which data pin DQ0-DQ7 of the devices under test DUT1 or DUT2 is connected to the respective input/output channel IO1-IO8 of the test system, when the relay matrix sections R1 and R2 are in the second position.

As can be seen from FIG. 2 and from the table above, for the core test of the of the first and second devices under test DUT1 and DUT2, all input/output channels IO1-IO8 of the test system are in the first relay position as indicated by continuous lines. In one embodiment, for the core test of the of the first and second devices under test DUT1 and DUT2, all input/output channels IO1-IO8 of the test system are in the second relay position as indicated by dotted lines.

For an interface test of the of the first device under test DUT1, the first relay matrix section R1 for the upper input/output channels IO1-IO4 of the test system may be in the first relay position, and the second relay matrix section R2 for the lower input/output channels IO5-IO8 of the test system may be in the second relay position. Under this relay matrix configuration, all eight input/output channels IO1-IO8 of the test system are contacting every pin of the first device under test DUT1. Thus, an interface test may be performed on the first device under test DUT1, whereas the second device under test DUT2 is not contacted.

In one embodiment, for an interface test of second device under test DUT2, the first relay matrix section R1 for the upper input/output channels IO1-IO4 of the test system may be in the second relay position, and the second relay matrix section R2 for the lower input/output channels IO5-IO8 of the test system may be in the first relay position. In this relay matrix setting, all eight input/output channels IO1-IO8 of the test system are contacting every pin of the second device under test DUT2. Thus, an interface test may be performed on the second device under test DUT2, whereas the first device under test DUT1 is not contacted.

According to another embodiment, for an interface test of a first device under test (DUT1 or DUT2), e.g., with a wiring for organization x8, the relay matrix R1, R2 for the test system can be adjusted so that the upper pin relays connected to the input/output channels IO1-IO4 are in the first position as indicated in FIG. 2 by continuous lines, and the pin relays connected to the input/output channels IO5-8 are in the second position as indicated in FIG. 2 by dotted lines. Thus, the connection between the input/output channels IO1-IO8 of the test system and the data pins (DQ0-DQ7) of the first device under test DUT1 are as indicated in the following table:

| | upper pin relays in the first position and lower pin |
|---|---|
| Tester IO pin | relays in the second position |
| IO1 | DUT1 DQ0 |
| IO2 | DUT1 DQ1 |
| IO3 | DUT1 DQ2 |
| IO4 | DUT1 DQ3 |
| IO5 | DUT1 DQ4 |
| IO6 | DUT1 DQ5 |
| IO7 | DUT1 DQ6 |
| IO8 | DUT1 DQ7 |

The first column of the table indicates the number of input/output channels of the test system; and the second column of the table indicates which data pin DQ0-DQ7 of the device under interface test DUT1 is connected to the respective input/output channels IO1-IO8 of the test system, when the first pin relays R1 connected to the upper input/output channels IO1-IO4 are in the first position and the second pin relays R2 connected to the lower input/output channels IO5-8 are in the second position.

In this arrangement or configuration, all input/output channels IO1-IO8 are connected with the data pins (DQ0-DQ7) of the first device under test DUT1, and the data pins (DQ0-DQ7) of the second device under test DUT2 are not connected to any of the input/output channels IO1-IO8 of the test system. Thus, an interface test or so called high speed test can be performed on the first device under test DUT1. Furthermore, a frequency doubling system (FDS) may be applied on the relay matrix or socket board to support the ability of the test systems to perform both core testing and interface testing.

According to another embodiment, for an interface test of a first device under test (DUT1 or DUT2), e.g., with a wiring for organization x8, the relay matrix or socket board for the test system can be adjusted so that the upper pin relays connected to the input/output channels IO1-IO4 are in the second position as indicated in FIG. 2 by dotted lines, and the pin relays connected to the input/output channels IO5-IO8 are in the first position as indicated in FIG. 2 by continuous lines. Thus, the connection between the input/output channels IO1-IO8 of the test system and the data pins DQ0-DQ7 of the second device under test DUT2 are as indicated in the following table:

| | upper pin relays in the second position and lower |
|---|---|
| Tester IO pin | pin relays in the first position |
| IO1 | DUT2 DQ0 |
| IO2 | DUT2 DQ1 |
| IO3 | DUT2 DQ2 |
| IO4 | DUT2 DQ3 |
| IO5 | DUT2 DQ4 |
| IO6 | DUT2 DQ5 |
| IO7 | DUT2 DQ6 |
| IO8 | DUT2 DQ7 |

The first column of the table indicates the number of input/output channels of the test system; and the second column of the table indicates which data pin DQ0-DQ7 of the second device under interface test DUT2 is connected to the respective input/output channels IO1-IO8 of the test system, when the upper pin relays connected to the input/output channels IO1-IO4 are in the second position as indicated by dotted lines, and the pin relays connected to the input/output channels IO5-IO8 are in the first position as indicated by continuous lines.

In this arrangement, all input/output channels IO1-IO8 are connected with the data pins (DQ0-DQ7) of the second device under test DUT2, and the data pins (DQ0-DQ7) of the first device under test DUT1 are not connected to any of the input/output channels IO1-IO8 of the test system. Thus, an interface test or so called high speed test can be performed on the second device under test DUT2.

According to another embodiment, for the core test and for the interface test of the a third and fourth devices under test (DUT 3 and DUT 4), further relay sections with further the input/output channels IO9-16 of the test system may be in correspondingly relay positions as described above.

By switching the relay sections R1 and R2 in the above described manner, a system and method for testing semiconductor devices is made available which can perform both testing of core and interface testing contents, e.g., the speed of the semiconductor devices, dies or chips or DRAMs. Core testing can be performed with partly connecting data pins of the device under test, and interface testing requires connecting of all data pins of the device under test.

In other words, the switching of the relay sections R1 and R2 according to the present invention offers the choice of selectively connecting data pins of the device under test with tester channels or connecting all data pins of the device under test with tester channels. Thereby, core testing systems can be enabled or can be used to perform both core testing and interface testing on semiconductor devices. Thus, a complete test insertion using the expensive high speed testers capable of interface testing can be saved.

While specific configurations and arrangements are discussed, it should be understood that this is done for illustrative purposes only. A person skilled in the pertinent art will recognize that other configurations and arrangements can be used without departing from the spirit and scope of the present invention. It will be apparent to a person skilled in the relevant art that this invention can also be employed in a variety of other applications.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A system for testing semiconductor devices, comprising:
parallel wiring paths; and
a test system being configured to be electrically connected via the parallel wiring paths to a plurality of contact pins of a number of devices under test,
the test system having at least one signal distribution matrix arranged in the wiring path to provide signals for testing and/or power supply to the devices.

2. The system of claim 1, comprising wherein the distribution matrix is configured to connect or to disconnect a number of wiring paths to the contact pins of the devices in dependence on the configuration of the distribution matrix.

3. The system of claim 1, comprising wherein the distribution matrix is configured to distribute signals for testing and/or power supply to all contact pins of a device under test or to a part of the contact pins of the device dependent on the configuration of the distribution matrix.

4. The system of claim 1, comprising wherein the distribution matrix is configured to distribute signals for testing and/or power supply to a first group of wiring paths or to a second group of wiring paths connected to contact pins of the devices.

5. The system of claim 1, comprising wherein the distribution matrix is configured to connect two or more tester channels with one contact pin of a device under test to provide frequency doubling.

6. The system of claim 1, wherein the distribution matrix comprises at least one relay matrix with a plurality of relays or switches arranged in the wiring paths connected to the contact pins of the devices.

7. The system of claim 1, wherein the distribution matrix comprises a number of matrix sections with a plurality of relays or switches arranged in the wiring paths connected to the contact pins of the devices.

8. The system of claim 1, comprising wherein at least one relay or switch is arranged in a wiring path connected to the contact pins of the devices.

9. The system of claim 6, comprising wherein the relays or switches are configured to connect or to disconnect a wiring path connected to a contact pin of the devices.

10. The system of claim 6, comprising wherein the relays or switches are configured to distribute signals for testing and/or power supply provided by the test system to a first wiring path or to a second wiring path connected to contact pins of the devices.

11. The system of claim 1, comprising wherein the distribution matrix provide a branching in the wiring paths to connect the test system to a first group of wiring paths or to a second group of wiring paths connected to contact pins of the devices.

12. The system of claim 1, comprising wherein the branching is configured to connect a number of tester channels of the test system to a first group of wiring paths or to a second group of wiring paths connected to contact pins of the devices.

13. The system of claim 1, comprising wherein at least one branching is installed in a wiring path providing a bifurcation of the tester channel.

14. The system of claim 1, comprising wherein the system is further configured to use a number of set of propagation delays to provide delays of test signals for timing measurements dependent on the configuration of the distribution matrix.

15. The system of claim 1, comprising wherein the distribution matrix is part of the system or part of an interface between a test system for testing semiconductor devices and the semiconductor devices to be tested.

16. An interface or probe card for connecting a test system for testing semiconductor devices with the semiconductor devices to be tested comprising:
at least one tester channel;
a plurality of parallel wiring paths, each wiring path configured to have a first end coupled to the tester channel and a second end configured to be coupled to a contact pin of separate devices under test; and
a distribution matrix arranged in the wiring path to provide signals for testing and/or power supply to the devices.

17. The interface or probe card of claim 16, comprising wherein the distribution matrix is configured to connect the tester channel with a first group of wiring paths or with a second group of wiring paths connected to contact pins of the devices.

18. A system for testing semiconductor devices comprising:
means for providing a test signal; and
means for distributing the test signal to a first group of wiring paths or to a second group of wiring paths connected to contact pins of the devices under test.

19. A method for testing semiconductor devices, comprising:
providing test signals from a test system via a number of tester channels; and
distributing the test signals via parallel wiring paths to a plurality of contact pins of a number of devices under test,
wherein the test signal is provided to the contact pins of the semiconductor devices by at least one distribution matrix arranged in the wiring path.

20. The method of claim 19, further comprising:
connecting or disconnecting a number of wiring paths to the contact pins of the devices by the distribution matrix in dependence on the configuration of the distribution matrix.

21. The method of claim 19, further comprising:
distributing signals for testing and/or power supply to a first group of wiring paths or to a second group of wiring paths connected to contact pins of the devices by the distribution matrix dependent on the configuration of the distribution matrix.

22. The method of claim 19, further comprising:
distributing signals for testing and/or power supply to all contact pins of a device under test or to a part of the contact pins of the device by using the distribution matrix.

23. The method of claim 19, further comprising:
wherein the distribution matrix comprises at least one relay matrix with a plurality of relays or switches arranged in the wiring paths connected to the contact pins of the devices.

24. The method of claim 19, further comprising:
connecting or disconnecting a number of tester channels to the contact pins of the devices by using at least one relay matrix with a plurality of relays or switches arranged in the wiring paths connected to the contact pins of the devices.

25. The method of claim 19, further comprising:
connecting or disconnecting a number of tester channels to the contact pins of the devices by using a number of matrix sections with a plurality of relays or switches arranged in the wiring paths connected to the contact pins of the devices.
